(19) United States
(12) Patent Application Publication
(10) Pub. No.: US 2010/0209624 A1
(43) Pub. Date: Aug. 19, 2010

(54) FILM-FORMING APPARATUS AND FILM-FORMING METHOD

(75) Inventor: Hiroyuki MATSUURA, Tokyo-To (JP)

Correspondence Address: SMITH, GAMBRELL & RUSSELL, 1130 CONNECTICUT AVENUE, N.W., SUITE 1130, WASHINGTON, DC, 20036, US

(73) Assignee: TOKYO ELECTRON LIMITED, Tokyo-To (JP)

(21) Appl. No.: 12/705,412

(22) Filed: Feb. 12, 2010

Related U.S. Application Data
(62) Division of application No. 11/384,350, filed on Mar. 21, 2006, now abandoned.

(30) Foreign Application Priority Data
Mar. 23, 2005 (JP) 2005-084829
Jan. 10, 2006 (JP) 2006-002343

(51) Int. Cl. C23C 16/52; C23C 16/50; C23C 16/00

(52) U.S. Cl. 427/579; 118/697; 118/723 E

(57) ABSTRACT

The present invention is a film-forming apparatus including: a longitudinal tubular processing container in which a vacuum can be created; an object-to-be-processed holding unit that holds a plurality of objects to be processed in a tier-like manner and that can be inserted into and taken out from the processing container; a heating unit provided around the processing container; a silane-based-gas supplying unit that supplies a silane-based gas into the processing container, the silane-based gas including no halogen element; a nitriding-gas supplying unit that supplies a nitriding gas into the processing container; an activating unit that activates the nitriding gas by means of plasma; and a controlling unit that controls the silane-based-gas supplying unit, the nitriding-gas supplying unit and the activating unit, in such a manner that the silane-based gas and the nitriding gas are supplied into the processing container at the same time while the nitriding gas is activated, in order to form a predetermined thin film on each of the plurality of objects to be processed.

### FIELD OF THE INVENTION

This invention relates to a film-forming apparatus and a film-forming method for forming a thin film on an object to be processed, such as a semiconductor wafer.

### BACKGROUND ART

In general, in order to manufacture a desired semiconductor integrated circuit, various thermal processes including a film-forming process, an etching process, an oxidation process, a diffusion process, a modifying process, a natural-oxide-film removing process or the like are carried out to a semiconductor wafer, which consists of a silicon substrate or the like. These thermal processes may be conducted by a longitudinal batch-type of thermal processing unit (For example, Japanese Patent laid-Open Publication No. Hei 6-34974 and Japanese Patent laid-Open Publication No. 2002-280378). In the case, at first, from a cassette that can contain a plurality of, for example 25 semiconductor wafers, semiconductor wafers are conveyed onto a longitudinal wafer boat. For example, 30 to 150 wafers (depending on the wafer size) are placed on the wafer boat in a tier-like manner. The wafer boat is conveyed (loaded) into a processing container that can be exhausted, through a lower portion thereof. After that, the inside of the processing container is maintained at an airtight state. Then, various process conditions including a flow rate of a process gas, a process pressure, a process temperature or the like are controlled to conduct a predetermined thermal process.

Herein, in order to improve characteristics of a semiconductor integrated circuit, it is important to improve characteristics of an insulation film in the integrated circuit. As an insulation film in the integrated circuit, in general, SiO₂, PSG (phospho Silicate Glass), P (Plasma)-SiO, P (Plasma)-SiN, SOG (Spin On Glass), Si₃N₄ (silicon nitride film), or the like may be used. Herein, in particular, the silicon nitride film is used in many cases because insulation performance thereof is better than a silicon oxide film and because the silicon nitride film can satisfactorily function as an etching stopper film and/or an interlayer insulation (dielectric) film.

In order to form the silicon nitride film on a surface of a semiconductor wafer, as a film-forming gas, a silane-based gas such as monosilane dichlorosilane (SiH₂Cl₂), hexachlorodisilane (Si₂Cl₆) or bis-tertial-butylaminosilane (BTBAS) may be used for a thermal CVD (Chemical Vapor Deposition) process in order to form the silicon nitride film. Concretely, in order to deposit a silicon nitride film, a combination of “SiH₂Cl₂+NH₃” (Japanese Patent laid-Open Publication No. Hei 6-34974) or a combination of “Si₂Cl₆+NH₃” or the like is selected for the thermal CVD process.

Recently, requests for much denser integration and more miniaturization for the semiconductor integrated circuit have been increased. Thus, in view of improvement of characteristics of circuit components, it is desired to lower the temperature of thermal history of a manufacturing step of a semiconductor integrated circuit.

Under such a situation, in the so-called longitudinal batch-type of thermal processing unit, source gases or the like may be supplied intermittently in order to repeatedly deposit a thin film of one or several atomic level or one or several molecular level (Japanese Patent laid-Open Publication No. Hei 6-45256 and Japanese Patent laid-Open Publication No. Hei 11-87341). Such a deposition method is generally referred to as an ALD (Atomic Layer Deposition) process, in which the wafer temperature can be maintained at a relatively low temperature (not subjected to a high temperature).

Herein, in the conventional film-forming method, the silicon nitride film (SiN) is formed by using a dichlorosilane (DCS) gas, which is a silane-based gas, and an NH₃ gas, which is a nitriding gas. Concretely, the DCS gas and the NH₃ gas are supplied in a processing container alternately and intermittently, and an RF (Radio Frequency) is applied to make plasma when the NH₃ gas is supplied, so that the nitriding reaction is promoted.

In the conventional ALD process, the silicon nitride film can be formed even when a wafer temperature is maintained at a relatively low temperature (not subjected to a high temperature). However, the silicon nitride film that has been formed by the above process has the following problems.

That is, in a recent semiconductor integrated circuit, such as a logic device consisting of CMOS or the like, it has been required to enhance an operation speed thereof much more. Thus, it is necessary to increase “mobility” thereof. For that purpose, in a silicon nitride film used for a CMOS transistor or the like in the logic device, a tensile stress of the silicon nitride film has to be not less than a predetermined value, in order to satisfactorily enlarge crystal lattice of a channel of the transistor.

However, in the silicon nitride film that has been formed by the conventional film-forming method, the tensile stress of the silicon nitride film is not high enough. In particular, if a design rule for a line width of the semiconductor integrated circuit is not more than 65 nm, the tensile stress of the silicon nitride film has to be not less than 1.5 GPa, which was not achieved by the silicon nitride film that has been formed by the conventional film-forming method.

### SUMMARY OF THE INVENTION

This invention is intended to solve the above problems. The object of this invention is to provide a film-forming apparatus and a film-forming method that can form a silicon nitride film at a relatively low temperature and that can achieve a sufficiently high tensile stress in the silicon nitride film.

This invention is a film-forming apparatus comprising: a longitudinal tubular processing container in which a vacuum can be created; an object-to-be-processed holding unit that holds a plurality of objects to be processed in a tier-like manner and that can be inserted into and taken out from the processing container; a heating unit provided around the processing container; a silane-based-gas supplying unit that supplies a silane-based gas into the processing container, the silane-based gas including no halogen element; a nitriding-gas supplying unit that supplies a nitriding gas into the processing container; an activating unit that activates the nitriding gas by means of plasma; and a controlling unit that controls the silane-based-gas supplying unit, the nitriding-gas supplying unit and the activating unit, in such a manner that the silane-based gas and the nitriding gas are supplied into the processing container at the same time while the nitriding gas is activated, in order to form a predetermined thin film on each of the plurality of objects to be processed.

According to the above invention, a silicon nitride film can be formed at a relatively low temperature. In addition, a tensile stress of the obtained silicon nitride film is sufficiently high.

For example, the processing container has: a cylindrical main part, and a nozzle-containing part protruding outwardly in a transversal direction from the main part, a shape of the nozzle-containing part being substantially uniform in a vertical direction; the nitriding-gas supplying unit has a nitriding-gas supplying nozzle extending in the nozzle-containing part; and a gas-discharging port for discharging an atmospheric gas in the processing container is provided at a side wall of the main part of the processing container on an opposite side to the nozzle-containing part.

In addition, for example, the activating unit has a radio-frequency electric power source and plasma electrodes connected to the radio-frequency electric power source; and the plasma electrodes are arranged in the nozzle-containing part.

In addition, for example, the silane-based-gas supplying unit has a silane-based-gas supplying nozzle extending in a vicinity of a connecting part between the main part and the nozzle-containing part of the processing container.

In addition, for example, a diluent-gas supplying system for supplying a diluent gas is connected to the silane-based-gas supplying unit.

In the case, preferably, the diluent gas consists of one or more gases selected from a group consisting of an H₂ gas, an N₂ gas and an inert gas.

In addition, preferably, the silane-based gas including no halogen element consists of one or more gases selected from a group consisting of monosilane (SiH₄), disilane (Si₂H₆), trisilane (Si₃H₈), hexamethyldisilazan (HMDS), disilylamine (DSA), trisilylamine (TSA), and bis-tertial-butylaminosilane (BTBAS).

In addition, preferably, the nitriding gas consists of one or more gases selected from a group consisting of an ammonium gas [NH₃], a nitrogen gas [N₂], a dinitrogen oxide gas [N₂O] and a nitrogen monoxide gas [NO].

In addition, preferably, the heating unit is adapted to heat the objects to be processed to a temperature within a range of 250 to 450° C.

In addition, preferably, a partial pressure of the silane-based gas including no halogen element supplied into the processing container is within a range of 2.1 to 3.9 Pa.

In addition, the present invention is a film-forming method comprising the steps of: loading a plurality of objects to be processed into a longitudinal tubular processing container in which a vacuum can be created; and forming a predetermined thin film on each of the plurality of objects to be processed by supplying a silane-based gas including no halogen element and a nitriding gas that has been activated by means of plasma at the same time into the processing container, while heating the plurality of objects to be processed.

According to the above invention, a silicon nitride film can be formed at a relatively low temperature. In addition, a tensile stress of the obtained silicon nitride film is sufficiently high.

In addition, the present invention is a storage unit capable of being read by a computer, storing a program to be executed by a computer in order to control a film-forming method, the film-forming method comprising a step of forming a predetermined thin film on each of a plurality of objects to be processed loaded into a longitudinal tubular processing container in which a vacuum can be created, by supplying a silane-based gas including no halogen element and a nitriding gas that has been activated by means of plasma at the same time into the processing container while heating the plurality of objects to be processed.

In addition, the present invention is a controller that controls a film-forming apparatus, the film-forming apparatus comprising: a longitudinal tubular processing container in which a vacuum can be created; an object-to-be-processed holding unit that holds a plurality of objects to be processed in a tier-like manner and that can be inserted into and taken out from the processing container; a heating unit provided around the processing container; a silane-based-gas supplying unit that supplies a silane-based gas into the processing container, the silane-based gas including no halogen element; a nitriding-gas supplying unit that supplies a nitriding gas into the processing container; and an activating unit that activates the nitriding gas by means of plasma; the controller being adapted to control the silane-based-gas supplying unit, the nitriding-gas supplying unit and the activating unit, in such a manner that the silane-based gas and the nitriding gas are supplied into the processing container at the same time while the nitriding gas is activated, in order to form a predetermined thin film on each of the plurality of objects to be processed.

In addition, the present invention is a program that causes a computer to execute a procedure for controlling a film-forming apparatus, the film-forming apparatus comprising: a longitudinal tubular processing container in which a vacuum can be created; an object-to-be-processed holding unit that holds a plurality of objects to be processed in a tier-like manner and that can be inserted into and taken out from the processing container; a heating unit provided around the processing container; a silane-based-gas supplying unit that supplies a silane-based gas into the processing container, the silane-based gas including no halogen element; a nitriding-gas supplying unit that supplies a nitriding gas into the processing container; and an activating unit that activates the nitriding gas by means of plasma; the procedure being adapted to control the silane-based-gas supplying unit, the nitriding-gas supplying unit and the activating unit, in such a manner that the silane-based gas and the nitriding gas are supplied into the processing container at the same time while the nitriding gas is activated, in order to form a predetermined thin film on each of the plurality of objects to be processed.

### BRIEF DESCRIPTION OF THE DRAWINGS

FIG. 1 is a schematic longitudinal sectional view showing an embodiment of a film-forming apparatus according to the present invention;

FIG. 2 is a schematic transversal sectional view showing the embodiment of FIG. 1;

FIG. 3 is a graph showing a relationship of tensile stress of a SiN film and uniformity of film-thickness within a wafer surface with respect to a wafer temperature; and

FIG. 4 is a graph showing a relationship of tensile stress of a SiN film and uniformity of film-thickness within a wafer surface with respect to a partial pressure of monosilane.

### DESCRIPTION OF THE PREFERRED EMBODIMENT

Hereinafter, an embodiment of a film-forming apparatus according to the present invention is explained with reference to attached drawings.

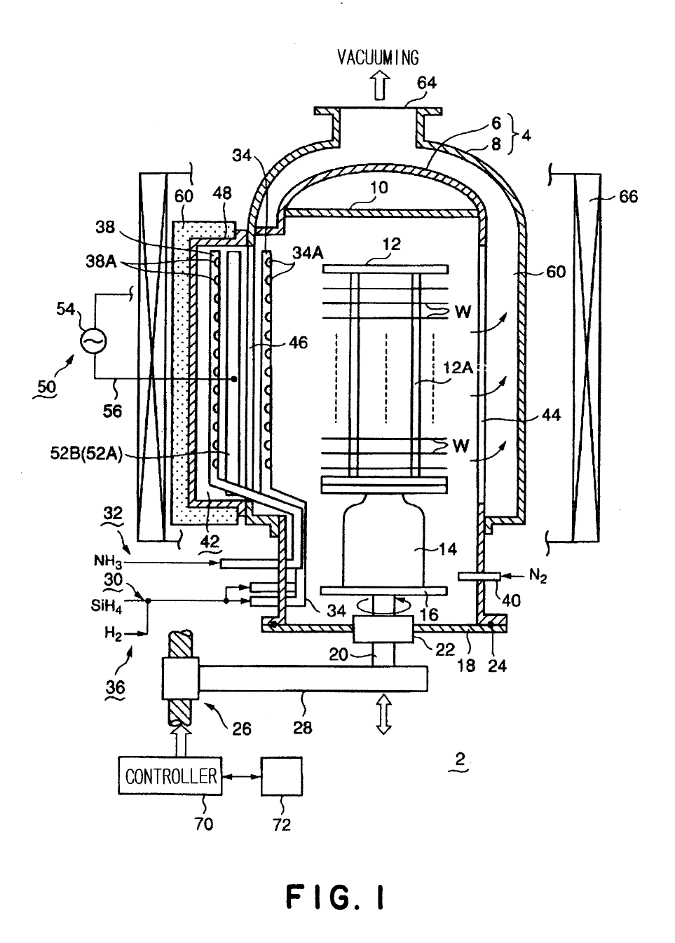

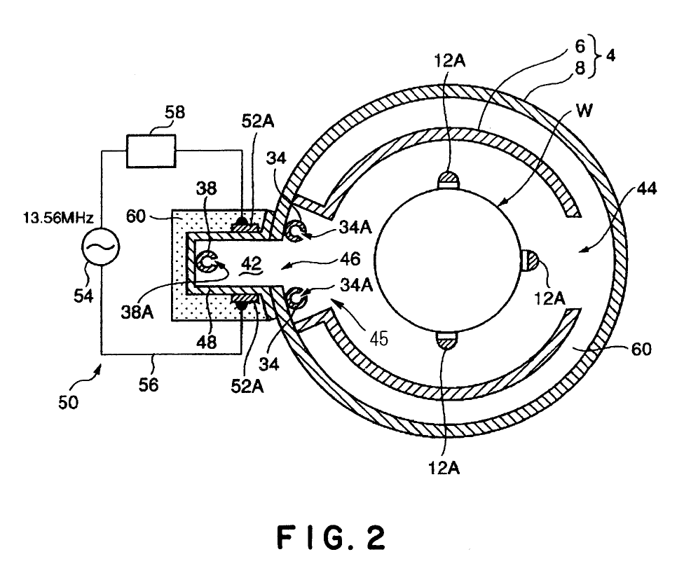

FIG. 1 is a schematic longitudinal sectional view showing an embodiment of a film-forming apparatus according to the present invention. FIG. 2 is a schematic transversal sectional view showing the embodiment of FIG. 1 (heating unit is omitted). In addition, herein, a monosilane (SiH₄) gas is used as a silane-based gas including no halogen element, and an ammonium (NH₃) gas is used as a nitriding gas, so that a silicon nitride film (SiN) is formed.

As shown in FIGS. 1 and 2, a film-forming apparatus 2 of the present embodiment has a substantially cylindrical processing container 4, which has a ceiling and a lower end with an opening. The processing container 4 is made of, for example, quartz.

More concretely, the processing container 4 consists of a substantially cylindrical inner tube 6 made of quartz, and an outer tube 8 made of quartz arranged coaxially around the inner tube 6 with a predetermined gap. A ceiling of the inner tube 6 is sealed by a ceiling plate 10 made of quartz. The height of the outer tube 8 is a little shorter than that of the inner tube 6. A lower end of the outer tube 8 is inwardly extended and welded to an outside periphery of the inner tube 6 at a position a little above a lower end of the inner tube 6. A space between the inner tube 6 and the outer tube 8 serves as a gas-discharging way.

The lower end of the inner tube 6 is supported by a base member not shown. A wafer boat 12 made of quartz, as an object-to-be-processed holding unit, can be inserted into the inner tube 6 through a lower opening of the inner tube 6. The wafer boat 12 can hold many semiconductor wafers W, as objects to be processed, in a tier-like manner. The wafer boat 12 can move vertically up and down, so that the wafer boat 12 can be inserted into and taken out from the inner tube 6. In the present embodiment, many supporting grooves (not shown) are formed at supporting columns 12A of the wafer boat 12. Thus, for example, about 30 semiconductor wafers W having a diameter of 300 mm are adapted to be supported at substantially regular intervals (pitches). Herein, instead of the supporting grooves, a circular supporting stage made of quartz may be fixed at the supporting columns 12A in order to support a wafer W thereon.

The wafer boat 12 is placed on a heat-insulation cylinder 14 made of quartz, which is placed on a table 16. The table 16 is supported on a rotation shaft 20 that pierces through a lid 18, which can open and close the lower opening of the inner tube 6 (the lower opening of the processing container 4). The lid 18 is made of, for example, stainless-steel. The rotation shaft 20 is provided at a penetration part of the lid 18 via a magnetic-fluid seal 22. Thus, the rotation shaft 20 can rotate while maintaining airtightness by the lid 18. In addition, a sealing member 24 such as an O-ring is provided between a peripheral portion of the lid 18 and a lower-end portion of the processing container 4. Thus, the lid 18 and the lower-end portion of the processing container 4 can be closed hermetically.

The rotation shaft 20 is attached to a tip end of an arm 28 supported by an elevating mechanism 26 such as a boat elevator. When the elevating mechanism 26 is moved up and down, the wafer boat 12 and the lid 18 and the like may be integrally moved up and down, and hence inserted into and taken out from the processing container 4. Herein, the table 16 may be fixed on the lid 18. In the case, the wafer boat 12 doesn't rotate while the process to the wafers W is conducted.

A silane-based-gas supplying unit 30 that supplies a silane-based gas including no halogen element such as chlorine and a nitriding-gas supplying unit 32 that supplies a nitriding gas are provided at a lower part of the processing container 4. A diluent-gas supplying unit 36 is connected to the silane-based-gas supplying unit 30. The diluent-gas supplying unit 36 supplies a diluent gas such as an H₂ gas. Concretely, the silane-based-gas supplying unit 30 has a silane-based-gas supplying nozzle 34, which pierces inwardly through a side wall of the processing container 4 (inner tube 6) at a lower portion thereof and bends upwardly in the processing container 4 (inner tube 6). The silane-based-gas supplying nozzle 34 is made of quartz. Herein, two silane-based-gas supplying nozzles 34 are provided. In each silane-based-gas supplying nozzle 34, a plurality of (a large number of) gas-ejecting holes 34A is formed at predetermined gaps in a longitudinal direction thereof. Thus, a mixed gas of monosilane and hydrogen may be ejected (supplied) as a laminar flow, substantially uniformly in a horizontal direction, from each gas-ejecting hole 34A.

In addition, the nitriding-gas supplying unit 32 has a nitriding-gas supplying nozzle 38, which pierces inwardly through the side wall of the processing container 4 (inner tube 6) at a lower portion thereof and bends upwardly in the processing container 4 (inner tube 6). The nitriding-gas supplying nozzle 38 is also made of quartz. In each nitriding-gas supplying nozzle 38, a plurality of (a large number of) gas-ejecting holes 38A is formed at predetermined gaps in a longitudinal direction thereof. Thus, an NH₃ gas to be activated by means of plasma may be ejected (supplied), substantially uniformly in a horizontal direction, from each gas-ejecting hole 38A.

If necessary, another N₂-gas nozzle 40 may be provided. The N₂-gas nozzle 40 may pierce inwardly through the side wall of the processing container 4 (inner tube 6) at a lower portion thereof. By means of the N₂-gas nozzle 40, an N₂ gas may be supplied into the processing container 4.

Herein, the above gases, that is, the monosilane gas, the H₂ gas, the NH₃ gas, and the N₂ gas if necessary, may be supplied at respective controllable flow rates. Their flow rates can be controlled by flow-rate controllers such as mass-flow controllers.

A nozzle-containing part 42 is formed at a portion of the side wall of the processing container 4, along a height direction thereof. Concretely, the nozzle-containing part 42 is formed to protrude outwardly in a transversal (horizontal) direction from the substantially cylindrical outer tube 8. The shape of the nozzle-containing part 42 is substantially uniform in a vertical direction. More concretely, as shown in FIG. 2, a part of the side wall of the outer tube 8 of the processing container 4 is cut off in the vertical direction by a predetermined width, so that a vertical longitudinal opening 46 is formed. Then, a vertical longitudinal partition-wall member 48 is hermetically welded to an outside periphery of the outer tube 8 so as to cover the opening 46. The partition-wall member 48 has a concave section of an U-shape. Then, the partition-wall member 48 forms the nozzle-containing part 42. That is, the nozzle-containing part 42 is formed integrally with the processing container 4. The partition-wall member 48 is made of, for example, quartz. The opening 46 is vertically long enough to cover all the wafers W held on the wafer boat 12 in the vertical direction.

In addition, a part of the side wall of the inner tube 6 on the side of the nozzle-containing part 42 is cut off in the vertical direction by another predetermined width greater than the width of the opening 46, so that a vertical longitudinal opening 45 is formed. The inner tube 6 is extended outwardly from both side edge portions of the opening 45 and hermetically welded to the inner surface of the outer tube 8. Thus, the inside space of the nozzle-containing part 42 communicates with the inside of the inner tube 6.

On the other hand, a part of the side wall of the inner tube 6 on the opposite side to the nozzle-containing part 42 is cut off in the vertical direction by another predetermined width, so that a vertical longitudinal gas-discharging port 44 is formed.

The nitriding-gas supplying nozzle 38 extending upwardly in the processing container 4 is bent outwardly in the radial direction of the processing container 4 on the way thereof, and then extends upwardly along a back surface of the nozzle-containing part 42 (the furthest away from the center of the processing container 4). On the other hand, the two silane-based-gas supplying nozzles 34 extend upwardly in the vicinity of the opening 46, inside the outer tube 8, on both sides of the opening 46.

Then, an activating unit 50 is provided at the nozzle-containing part 42 in order to activate the NH₃ gas by means of plasma. Concretely, the activating unit 50 has a pair of longitudinal plasma electrodes 52A, 52B. The longitudinal plasma electrodes 52A, 52B are arranged in the vertical direction on respective outside surfaces of both side walls of the partition-wall member 48 so as to be opposite to each other. The longitudinal plasma electrodes 52A, 52B are connected to a radio-frequency electric power source 54 for generating plasma, via cables 56.

For example, when a radio-frequency electric voltage of 13.56 MHz is applied between the plasma electrodes 52A, 52B, the NH₃ gas is made into plasma, that is, the NH₃ gas is activated. Herein, the frequency of the radio-frequency electric voltage is not limited to 13.56 MHz, but may be any other frequency, for example 400 kHz. In addition, a matching circuit 58 for impedance matching is provided on the way of the cables 56. Thus, the ammonium gas ejected from the gas-ejecting holes 38A of the nitriding-gas supplying nozzle 38 flows while being diffused, toward the center of the processing container 4 in the radial direction thereof, under a condition decomposed and/or activated by mean of plasma. An insulation-and-protection cover 60, for example made of quartz, is fixed on the outside surface of the partition-wall member 48 so as to cover the same.

On the other hand, outside the gas-discharging port 44, a gas-discharging way 60 is formed between the inner tube 6 and the outer tube 8. The gas-discharging way 60 is connected to a vacuum system including a vacuum pump not shown, via a gas outlet 64 (see FIG. 1) at an upper portion of the processing container 4. Thus, a vacuum may be created in the gas-discharging way 60.

In addition, a cylindrical heating unit 66 for heating the processing container 4 and the wafers W in the processing container 4 is provided so as to surround the outside periphery of the processing container 4.

The whole operation of the film-forming apparatus 2 is controlled by a controller 70 including a computer and the like. For example, the controller 70 controls flow rates of the above respective gases, and/or controls supply/stop of each of the gases. In addition, the controller 70 controls a pressure in the processing container 4. Furthermore, the controller 70 controls the whole operation of the film-forming apparatus 2.

The controller 70 has a storage medium 72 such as a flash memory or a hard disk or a floppy disk, which stores a program for conducting the above controls.

Next, a plasma processing method conducted by using the above film-forming apparatus 2 is explained. Herein, as a plasma process, a silicon nitride film is formed on each of surfaces of wafers by a plasma CVD process.

At first, a large number of, for example 50, wafers W having a diameter of 300 mm at a normal temperature are placed on the wafer boat 12. Then, the wafer boat 12 is loaded into the processing container 4 that has been adjusted to a predetermined temperature, through the lower opening of the processing container 4. Then, the lid 18 closes the lower opening of the processing container 4 so that the processing container is hermetically sealed.

Then, the inside of the processing container 4 is vacuumed to a predetermined process pressure. In addition, supply electric power to the heating unit 66 is increased so that the wafers W are heated to a process temperature.

On the other hand, the NH₃ gas and the monosilane gas that is an example of the silane-based gas including no halogen element are respectively supplied continuously at the same time from the silane-based-gas supplying unit 30 and the nitriding-gas supplying unit 32. At that time, the monosilane gas, whose flow rate is small, is supplied while being diluted by the H₂ gas as a carrier gas. At the same time, a radio-frequency electric voltage is applied between the plasma electrodes 52A and 52B of the activating unit 50. Thus, the NH₃ gas is made into plasma, activated, and supplied toward the center of the processing container 4 in the radial direction thereof. Thus, a silicon nitride film is formed on each of surfaces of the wafers W supported by the rotating wafer boat 12.

More concretely, the NH₃ gas is ejected in the horizontal direction from the respective gas-ejecting holes 38A of the nitriding-gas supplying nozzle 38 provided in the nozzle-containing part 42. In addition, the monosilane gas is ejected in the horizontal direction from the respective gas-ejecting holes 34A of the silane-based-gas supplying nozzle 34. The ejection of the both gases is conducted continuously and at the same time. Thus, the both gases react with each other, so that the silicon nitride film is formed. At that time, the radio-frequency electric voltage from the radio-frequency electric power source 54 is applied between the plasma electrodes 52A and 52B. Thus, the NH₃ gas ejected from the gas-ejecting holes 38A of the nitriding-gas supplying nozzle 38 flows into the space between the plasma electrodes 52A and 52B, and is made into plasma and is activated in the space, so that radicals (active species) such as N*, NH*, NH₂* and NH₃* are generated (the sign “*” means radical). The radicals are ejected and diffused toward the center of the processing container 4 in the radial direction thereof through the opening 46 of the nozzle-containing part 42, so as to flow between the wafers W as a laminar flow. Then, the above radicals react with molecules of the monosilane gas that have been stuck to the surfaces of the wafers W, so that the silicon nitride film is formed as described above.

Herein, the silane-based-gas including no halogen element is used in order to prevent generation of ammonium chloride or the like. If the gas includes any halogen element such as chlorine, ammonium chloride or the like may be generated. Such ammonium chloride or the like may be stuck to an inside surface of the processing container 4 and/or the gas-discharging system, so that particles may be generated and/or occlusion of the gas-discharging pipe may be caused.

Herein, the process condition is explained. The process temperature (wafer temperature) is within a range of 250 to 450° C., for example about 300° C. The process pressure is within a range of 5 mTorr (0.7 Pa) to 1 Torr (133 Pa), for example about 50 mT (7 Pa). The flow rate of the monosilane gas is within a range of 5 to 200 sccm, for example 30 sccm. The flow rate of the H₂ gas is within a range of 50 to 400 sccm, for example 100 sccm. The flow rate of the NH₃ gas is within a range of 100 to 1000 sccm, for example 300 sccm. The RF (radio frequency) power is for example 50 watt, and the frequency of the RF power is 13.56 MHz. The number of wafers is about 25 when the wafers have a diameter of 300 mm. According to the above process condition, the film-forming rate is about 0.5 to 1 nm/min.

Herein, if a thin film whose heat resistance is especially low, for example a NiSi film whose melting point is about 430° C., is included in a base layer, it is preferable that the process temperature is set not higher than 400° C. in order to prevent deterioration of characteristics of the NiSi film.

As described above, the silicon nitriding film of the present embodiment can be formed at a relatively low temperature. In addition, it was found that tensile stress of the silicon nitriding film is much higher than that of a silicon nitride film that has been formed by the conventional method. As a result, if the silicon nitride film of the present embodiment is applied to a transistor such as a CMOS, crystal lattice of a channel of the transistor can be sufficiently enlarged, and the “mobility” can be also increased, so that an integrated circuit operable with a higher speed can be formed. Thus, even if a design rule for a line width of an integrated circuit becomes more severe, it is possible to form a satisfactory semiconductor integrated circuit.

In addition, in order to maintain uniformity of film thickness within a wafer surface at a high level while maintaining the tensile stress in the silicon nitride film to a desired value, for example not less than 1.4 GPa, it is preferable that the wafer temperature at the film-forming step is set within a range of 250 to 450° C., and it is preferable that a partial pressure of the monosilane gas is set within a range of 2.1 to 3.9 Pa.

In addition, after the silicon nitride film is formed, an ultraviolet radiation process with a low-temperature heating step of 350 to 450° C. may be conducted to obtain a tensile stress of 1.5 GPa. This is particularly preferable.

In addition, as described above, the silicon nitride film can be formed at a relatively low temperature. Thus, even if a material whose heat resistance is weak is used as a base layer, thermal damage of the base layer can be inhibited. In addition, as the silicon nitride film is formed at a relatively low temperature, it is possible to make an etching rate of the silicon nitride film much lower than that of a SiO₂ film which may be used as an insulation film at a device forming step. That is, selectivity of the silicon nitride film against the SiO₂ film at an etching process may be increased. In particular, in the present embodiment, regarding the above silicon nitride film, an etching rate of not higher than 6.5 nm/min can be achieved, which is required as a contact etching stopper. In addition, according to the present embodiment, as described above, both uniformity of thickness of the silicon nitride film within each wafer surface and uniformity of thicknesses of the silicon nitride films between wafer surfaces can be maintained high. In addition, according to the present embodiment, generation of reaction byproducts, which may cause occlusion of the gas-discharging system, was scarcely found.

In addition, in the present embodiment, since the film-forming gases are continuously supplied, the film-forming rate may be remarkably increased compared with the conventional so-called ALD film-forming method wherein the film-forming gases are intermittently supplied. For example, the film-forming rate is 1 to 2 Å/min in the conventional ALD film-forming method, while the film-forming rate is 5 to 10 Å/min in the present embodiment.

Herein, comparisons are explained.

### <Comparison 1>

In Comparison 1, the reaction energy was only heat. That is, the NH₃*(active species) generated by ammonium plasma was not used.

Then, a silicon nitride film is deposited by a thermal CVD process and by a thermal ALD process, both of which use an SiH₄ gas and an NH₃ gas.

As a result, energy of the nitriding reaction of “SiH₄₊NH₃→N₃Si—NH₂” or the like was as great as 2 eV. Thus, it was confirmed that it is difficult to form a silicon nitride film at a low temperature not higher than 500° C. by means of the above both processes.

### <Comparison 2>

In Comparison 2, an ALD process was conducted by alternately and intermittently supplying an SiH₄ gas that has not been activated and an NH₃ gas that has been activated by plasma, at a low temperature not higher than 500° C.

As a result, it was confirmed that the silicon nitride film is scarcely generated. The reason is as follows. When the NH₃*(active species) generated by plasma nitrides the wafer surfaces, “—NH₂” group remains on the wafer surfaces. Then, absorptive reaction of the SiH₄ with an N atom of the “—NH₂” group is scarcely generated at a low temperature not higher than 500° C.

### <Comparison 3>

In Comparison 3, a plasma CVD process was conducted by supplying at the same time an SiH₄ gas and an NH₃ gas, by making the both gases into plasma and activating the both gases, and by using generated reaction intermediates and active species, in order to form a silicon nitride film.

As a result, the reaction intermediates and active species which contribute to the film-forming process were located locally at a plasma-generating portion and its vicinity, so that the film was deposited there too much. That is, it was confirmed that uniformity of film thickness is remarkably bad (not preferable).

### <Comparison 4>

In Comparison 4, an ALD process was conducted by alternately and intermittently supplying an SiH₄ gas that has been activated by plasma and an NH₃ gas that has been activated by plasma.

As a result, amorphous Si of SiH₄* was formed at the plasma-generating portion, in the processing container, and on the wafer surfaces. That is, it was confirmed that this film-forming method is not appropriate.

As described above, it was confirmed that the comparisons 1 to 4 are not appropriate for forming a silicon nitride film.

Herein, in the above embodiment, the supply flow rate of the monosilane gas is very small. Thus, the diluent gas functioning as a carrier gas is used to make the gas diffusion more uniform. As the diluent gas, instead of the H₂ gas, any other inert gas such as an N₂ gas, a He gas, an Ar gas and a Ne gas may be used. Taking into consideration improvement of the film-forming rate and improvement of uniformity of film thickness within a wafer surface, the H₂ gas is preferable as the diluent gas. The reason is as follows. The H₂ gas is the most lightweight, and collision cross-section thereof is the smallest. Thus, activated ammonium molecules in a vibration excitation condition collide with the H₂ gas less often, so that the activated ammonium molecules lose less activity. That is, the ammonium active species can contribute to the deposition of the silicon nitride film more effectively. Thus, the film-forming rate of the silicon nitride film is higher. In addition, lifetime of the active species is also longer, so that the active species can reach centers of the wafers sufficiently. Thus, the uniformity of film thickness within a wafer surface can be also improved.

Herein, regarding the tensile stress of the silicon nitride film (SiN film), optimization of the wafer temperature and the partial pressure of the monosilane gas is explained.

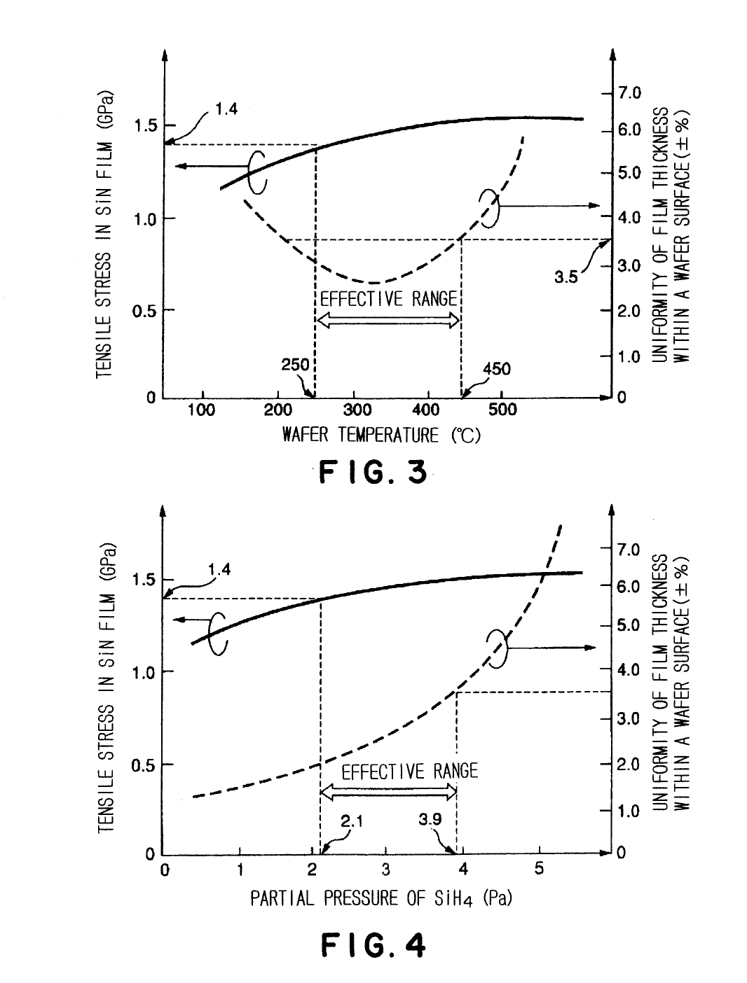

FIG. 3 is a graph showing a relationship of tensile stress of a SiN film and uniformity of film-thickness within a wafer surface with respect to a wafer temperature. Regarding the film-forming condition of FIG. 3, the film-forming temperature was variable, the film-forming pressure was 13 Pa, the flow rate of the SiH₄ gas was 113 sccm, the flow rate of the H₂ gas was 87 sccm, the flow rate of the NH₃ gas was 300 sccm, the RF power was 50 watt, and the RF frequency was 13.56 MHz.

As shown in FIG. 3, the tensile stress of the silicon nitride film is increased little by little as the wafer temperature is increased. On the other hand, the uniformity of film-thickness within a wafer surface has a minimum value at about 350° C. When the wafer temperature is both higher and lower than that temperature, the uniformity of film-thickness within a wafer surface is deteriorated. Thus, when the lower limit of the tensile stress is 1.4 GPa and the upper limit of the uniformity of film-thickness within a wafer surface is ±3.5%, it is preferable that the wafer temperature is set within a range of 250 to 450° C.

Next, FIG. 4 is a graph showing a relationship of tensile stress of a SiN film and uniformity of film-thickness within a wafer surface with respect to a partial pressure of monosilane. Regarding the film-forming condition of FIG. 4, the film-forming temperature was 300° C., the film-forming pressure was 13 Pa, the flow rate of the SiH₄ gas was variable, the flow rate of the SiH₄ gas+the H₂ gas was 200 sccm, the flow rate of the NH₃ gas was 300 sccm, the RF power was 50 watt, and the RF frequency was 13.56 MHz.

As shown in FIG. 4, the tensile stress of the silicon nitride film is increased little by little as the partial pressure of the monosilane gas is increased. On the other hand, the uniformity of film-thickness within a wafer surface is rapidly deteriorated as the partial pressure of the monosilane gas is increased. Thus, similarly to the above, when the lower limit of the tensile stress is 1.4 GPa and the upper limit of the uniformity of film-thickness within a wafer surface is ±3.5%, it is preferable that the partial pressure of the monosilane gas is set within a range of 2.1 to 3.9 Pa.

In addition, in the above film-forming apparatus 2, the two silane-based-gas supplying nozzles 34 are arranged at the both side portions of the opening 46 in order to promote the mixing of the silane-based gas with the active species of the NH₃ gas. However, this invention is not limited thereto. The silane-based-gas supplying nozzle may be only one.

Regarding the nozzle-containing part 42 having the plasma electrodes 52A and 52B, a plurality of nozzle-containing parts may be provided adjacently.

The processing container is not limited to the double-tube type of processing container 4 having the inner tube 6 and the outer tube 8. That is, a single-tube type of processing container may be used.

In the above embodiment, the plasma of the NH₃ gas is generated by the radio-frequency electric power source 54 of the activating unit 50. However, the plasma of the NH₃ gas may be generated by microwave of 2.45 GHz or the like.

In addition, in the above embodiment, the monosilane gas is used as the silane-based gas including no halogen element. However, this invention is not limited thereto. The silane-based gas including no halogen element may consist of one or more gases selected from a group consisting of monosilane (SiH₄), disilane (Si₂H₆), trisilane (Si₃H₈), hexamethyldisilazan (HMDS), disilylamine (DSA), trisilylamine (TSA), and bis-tertial-butylaminosilane (BTBAS).

In addition, in the above embodiment, the NH₃ gas is used as the nitriding gas. However, this invention is not limited thereto. The nitriding gas may consist of one or more gases selected from a group consisting of an ammonium gas [NH₃], a nitrogen gas [N₂], a dinitrogen oxide gas [N₂O] and a nitrogen monoxide gas [NO].

The object to be processed is not limited to the semiconductor wafer, but may be a glass substrate, a LCD substrate, a ceramics substrate or the like.

1-10. (canceled)

11. A film-forming method forming a predetermined thin film, said method comprising the steps of:
loading a plurality of objects to be processed into a longitudinal tubular processing container in which a vacuum can be created,
continuously supplying a silane-based gas including no halogen element into the processing container,
at the same time as the silane-based gas is continuously supplied, continuously supplying a nitriding gas into the processing container while activating the nitriding gas by forming a plasma thereof, and
heating the plurality of objects to be processed,
wherein said steps of continuously supplying the silane-based gas and continuously supplying the nitriding gas are continued until the predetermined thin film is formed on each of the plurality of objects.

12. A storage unit capable of being read by a computer, storing instructions to be executed by a computer for performing steps forming a predetermined thin film, said steps comprising:
step (A) of loading each of a plurality of objects to be processed into a longitudinal tubular processing container in which a vacuum can be created,
step (B) of continuously supplying a silane-based gas including no halogen element and into the processing container,
step (C), of at the same time as the silane-based gas is continuously supplied, continuously supplying a nitriding gas into the processing container while activating the nitriding gas by forming a plasma thereof, and
step (D) of heating the plurality of objects to be processed,
wherein steps (B) and (C) are continued until the predetermined thin film is formed on each of the plurality of objects.

13. A film-forming method according to claim 11,
supplying a diluent gas directly to the silane-based-gas while supplying the silane-based gas.

14. A film-forming apparatus according to claim 13, wherein
the diluent gas consists of one or more gases selected from a group consisting of an H₂ gas, an N₂ gas and an inert gas.

15. A film-forming method according two claim 11, wherein the plasma is activated by plasma electrodes connected to a radio-frequency electric power source.

16. A film-forming method according to claim 11, wherein the silane-based gas including no halogen element consists of one or more gases selected from a group consisting of monosilane (SiH₄), disilane (Si₂H₆), trisilane (Si₃H₈), hexamethyldisilazan (HMDS), disilylamine (DSA), trisilylamine (TSA), and bis-tertial-butylaminosilane (BTBAS).

17. A film-forming method according to claim 11, wherein the nitriding gas consists of one or more gases selected from a group consisting of an ammonium gas [NH₃], a nitrogen gas [N₂], a dinitrogen oxide gas [N₂O], and a nitrogen monoxide gas [NO].

18. A film-forming method according to claim 11, wherein the objects to be processed are heated to a temperature within a range of 250 to 450° C.

19. A film-forming method according to claim 11, wherein a partial pressure of the silane-based gas including no halogen element supplied into the processing container is within a range of 2.1 to 3.9 Pa.
